(19) United States
(12) Patent Application Publication
(10) Pub. No.: US 2007/0254218 A1
(43) Pub. Date: Nov. 1, 2007

(54) Phase shifting mask capable of reducing the optical proximity effect and method for preparing semiconductor devices using the same

(75) Inventor: Yee Kai Lai, Jungli (TW)

Correspondence Address: OLIFF & BERRIDGE, PLC, P.O. BOX 19928, ALEXANDRIA, VA, 22320, US

(73) Assignee: Promos Technologies Inc., Hsinchu (TW)

(21) Appl. No.: 11/449,658

(22) Filed: Jun. 9, 2006

(30) Foreign Application Priority Data
Apr. 28, 2006 (TW) 095115212

(51) Int. Cl. G03C 5/00; G03F 1/00

(52) U.S. Cl. 430/5; 430/311

(57) ABSTRACT

A phase shifting mask capable of decreasing the optical proximity effect comprises a substrate and at least one phase shifting pattern positioned on the substrate, wherein the phase shifting pattern surrounds at least one optical correction pattern. Preferably, the optical correction pattern is an aperture exposing the substrate, and positioned on an intersection or a corner of the phase shifting pattern. The method for preparing the phase shifting mask comprises steps of forming a polymer layer on a substrate, illuminating a first predetermined region of the polymer layer by an electron beam to change the molecular structure of the polymer layer in the first predetermined region, which surrounds at least one second predetermined region. Subsequently, the polymer layer outside the first predetermined region is removed to form a phase shifting pattern, while the second predetermined region forms an optical correction pattern.

### BACKGROUND OF THE INVENTION

(A) Field of the Invention

The present invention relates to a phase shifting mask and method for preparing semiconductor devices using the same, and more particularly, to a chromeless phase shifting mask and method for preparing semiconductor devices using the same.

(B) Description of the Related Art

As sizes of critical dimensions (CD) of desired patterns are reduced and approach the resolution limit of lithography equipment, the consistency between the mask pattern and the actual layout pattern developed in the photoresist on the silicon wafer is significantly reduced. Proximity effect in a lithographic process can arise during exposing, photoresist pattern formation and subsequent pattern transferring steps such as etching. To solve the proximity effect, an opaque chrome pattern that reduces this effect is added to certain regions having more serious proximity effects, such as corners of mask patterns.

FIG. 1(a) illustrates a chromeless phase shifting mask 40 according to the prior art, and FIG. 1(b) shows a simulated optical intensity distribution on a portion of the chromeless phase shifting mask 40 (i.e., the dash-lined region) using an optical simulation software called SOLID-E. As shown in FIG. 1(b), there is a discontinuity at the intersection of the line-shaped pattern 42 of the chromeless phase shifting mask 40, which is not the same as the desired pattern with continuous line-shaped pattern 42.

FIG. 2(a) illustrates a partial chromeless phase shifting mask 40′ according the prior art, and FIG. 2(b) shows a simulated optical intensity distribution on a portion of the partial chromeless phase shifting mask 40′ using the SOLID-E. In comparison with the chromeless phase shifting mask 40 in FIG. 1(b), the partial chromeless phase shifting mask 40′ in FIG. 2(a) has an auxiliary pattern 44 made of chrome material at the intersection of the line-shaped pattern 42. The shading effect of the auxiliary pattern 44 can avoid the occurrence of the discontinuity at the intersection of the line-shaped pattern 42, as shown in FIG. 2(b).

The preparation of the partial chromeless phase shifting mask 40′ requires performing the lithographic process twice for patterning photoresist layers used to define positions of the phase shifting patterns such as the line-shaped pattern 44 and the position of some auxiliary patterns such as the auxiliary pattern 44, respectively. However, performing the lithographic process twice not only increases the alignment control difficulty, but also limits the throughput of the mask.

### SUMMARY OF THE INVENTION

One aspect of the present invention provides a phase shifting mask capable of reducing the optical proximity effect.

A phase shifting mask according to this aspect of the present invention comprises a substrate, at least one phase shifting pattern positioned on the substrate and at least one optical correction pattern being a transparent region of the substrate, wherein the phase shifting pattern surrounds the optical correction pattern. Preferably, the optical correction pattern is an aperture exposing the substrate, and the phase shifting pattern has a corner or an intersection and the optical correction pattern is positioned at the corner or at the intersection.

Another aspect of the present invention provides a method for preparing a semiconductor device using a chromeless phase shifting mask capable of reducing the proximity effect. The chromeless phase shifting mask comprises a phase shifting pattern including polymer material, and the preparation of the chromeless phase shifting mask does not need to perform the lithographic process or the etching process for patterning the opaque chrome pattern, solving the problems of mask inspection, phase error and alignment originating from performing the lithographic process twice and etching process at least twice.

In comparison with the prior art using the auxiliary pattern made of chrome to reduce the optical proximity effect, the chromeless phase shifting mask in accordance with one embodiment of the present invention comprises an optical correction pattern in phase shifting patterns to reduce the optical proximity effect. Further, the preparation of the conventional chromeless phase shifting mask needs to perform the lithographic process twice and etching process, while the preparation of the phase shifting mask according to one embodiment of the present invention does not to perform the lithographic process or etching process such that the throughput of the mask can be increased.

### BRIEF DESCRIPTION OF THE DRAWINGS

The objectives and advantages of the present invention will become apparent upon reading the following description and upon reference to the accompanying drawings in which:

FIG. 1(a) illustrates a chromeless phase shifting mask according to the prior art;

FIG. 1(b) shows a simulated optical intensity distribution on a portion of the chromeless phase shifting mask using an optical simulation software called SOLID-E according to the prior art;

FIG. 2(a) illustrates a partial chromeless phase shifting mask according to the prior art;

FIG. 2(b) shows a simulated optical intensity distribution on a portion of the partial chromeless phase shifting mask using the SOLID-E according to the prior art;

FIG. 3 to FIG. 5 illustrates a chromeless phase shifting mask according to one embodiment of the present invention;

FIG. 6 shown a simulated optical intensity distribution on a portion of the chromeless phase shifting mask using the SOLID-E according to one embodiment of the present invention;

FIG. 7 is a diagram showing the variation of the reflection index of the phase shifting pattern under different wavelengths according to one embodiment the present invention;

FIG. 8 is a diagram showing the variation of the extinction coefficient of the phase shifting pattern under different wavelengths according to one embodiment the present invention;

FIG. 9 is a schematic diagram showing the application of the phase shifting mask to pattern the shapes of semiconductor devices on a semiconductor substrate according to one embodiment of the present invention;

FIG. 10(a) illustrates a chromeless phase shifting mask 90 according to the prior art;

FIG. 10(b) shows simulated optical intensity distribution of the chromeless phase shifting mask using the SOLID-E according to the prior art;

FIG. 11(a) illustrates a phase shifting mask according to the prior art;

FIG. 11(b) shows simulated optical intensity distribution of the phase shifting mask using the SOLID-E according to the prior art;

FIG. 12(a) illustrates a chromeless phase shifting mask according to another embodiment of the present invention; and

FIG. 12(b) shows a simulated optical intensity distribution of the chromeless phase shifting mask using the SOLID-E according to another embodiment of the present invention.

### DETAILED DESCRIPTION OF THE INVENTION

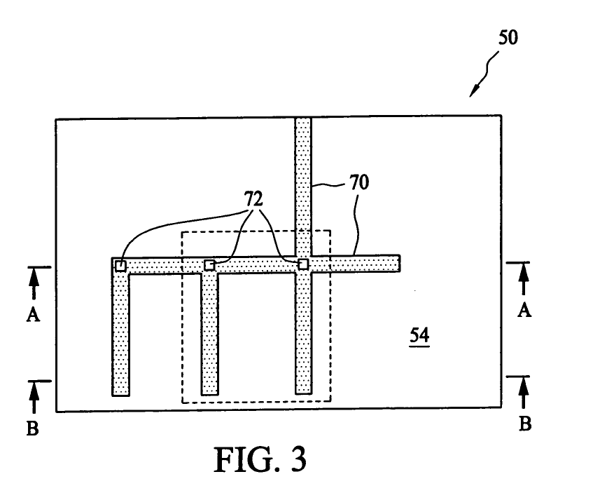

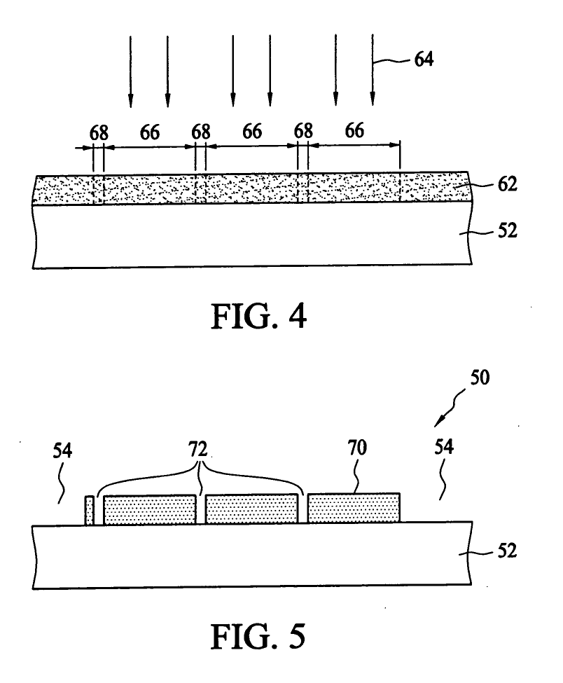

FIG. 3 to FIG. 5 illustrate a chromeless phase shifting mask 50 according to one embodiment of the present invention, wherein FIG. 4 and FIG. 5 are cross-sectional diagrams along a cross-sectional line A-A in FIG. 3. A polymer layer 62 is formed on a substrate 52 by a spin-coating process, and energy is then selectively transferred to the polymer layer 62 in a first region 66, such as irradiating an electron beam 64 to the first region 66, to change the chemical properties of the polymer layer 62 in the first region 66, i.e., to generate cross-linking of the polymer layer 62 in the first region 66, as shown in FIG. 4. Particularly, the irradiation of the electron beam 64 will change the molecular structure of the polymer in the first region 66. The first region 66 surrounds a second region 68 and the electron beam 64 does not irradiate on the second region such that the molecular structure of the polymer layer 62 in the second region 68 substantially remains the same.

Referring to FIG. 5, a developing process is performed to remove a portion of the polymer layer 62 not irradiated by the electron beam 64, i.e., the polymer layer 62 outside the first region 66, while the polymer layer 62 inside the first region 66 remains to form a phase shifting pattern 70 on the substrate 52, as shown in FIG. 3, which is a top view of the chromeless phase shifting mask 50. Particularly, the phase shifting pattern 70 surrounds at least one optical correction pattern 72, whose position corresponds to the second region 68. Preferably, the optical correction pattern is an aperture exposing the substrate 52, i.e., a transparent region, and the refraction index of the phase shifting pattern 70 is different from that of the optical correction pattern 72. Taking a portion of the substrate 52 not occupied by the phase shifting pattern 70 and the optical correction pattern 72 as a zero-degree region 54, the optical correction pattern 72 does not contact the zero-degree region 54, i.e., the peripheral of the optical correction pattern 72 is the phase shifting pattern 70. In other words, the optical correction pattern 72 is positioned inside the phase shifting pattern 70, and does not connect to the outer border of the phase shifting pattern 70.

In a preferred embodiment, the phase shifting pattern 70 has a corner or an intersection and the optical correction pattern 72 is positioned at the corner or the intersection to avoid the occurrence of the corner rounding or discontinuity of the phase-shifting pattern 70 due to the optical proximity effect. In addition, the optical correction pattern 72 can be optionally positioned on a free end of the phase shifting pattern 70 to avoid the occurrence of line-end rounding or line-end shorting.

Since the electron beam 64 provides energy for the polymer to change the molecular structure, the solubility to a developer of the polymer irradiated by the electron beam 64 is different from that of the polymer not irradiated by the electron beam 64. Consequently, the developing process can selectively remove the portion of the polymer layer 62 not irradiated by the electron beam 64, i.e., removing the portion of the polymer layer 62 outside the first region 66, while maintaining the other portion of the polymer layer 62 in the first region 66. In addition, the substrate 52 can be quartz substrate, or a substrate with an interface layer thereon, wherein the interface layer can be a conductive layer made of conductive polymer such as cis-polystyrene and polyaniline, or a glue layer made of hexamethyldisilazane.

The polymer layer 62 may be made of material including silsesquioxane. For example, the silsesquioxane can be hydrogen silsesquioxane (HSQ), and a developing process using alkaline solution can be performed to remove the polymer layer 62 not irradiated by the electron beam 64, wherein the alkaline solution is selected from the group consisting of sodium hydroxide (NaOH) solution, potassium hydroxide (KOH) solution, and tetramethylamomnium hydroxide (TMAH) solution. In addition, the silsesquioxane can be methylsilsesquioxane (MSQ), and a developing process using an alcohol solution such as an ethanol solution is performed to remove the polymer layer 62 not irradiated by the electron beam 64. Further, the polymer layer 62 can be made of material including hybrid organic siloxane polymer (HOSP), and a developing process using a propyl acetate solution is performed to remove the polymer layer 62 not irradiated by the electron beam 64. The irradiation of the electron beam 64 will change the molecular structure of the polymer layer 62, for example, the molecular structure of hydrogen silsesqnioxane will transform into a network structure from a cage-like structure and chemical bonds will be formed between the polymer layer 62 and the quartz substrate 52. As a result, it is possible to selectively remove the polymer layer 62 outside the first region 66 by a developing process using the alkaline solution.

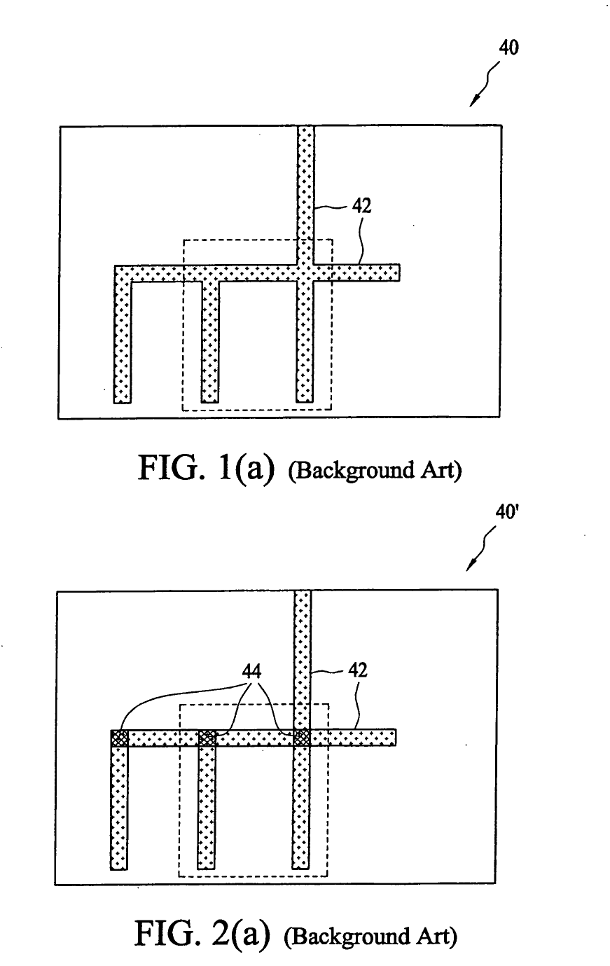

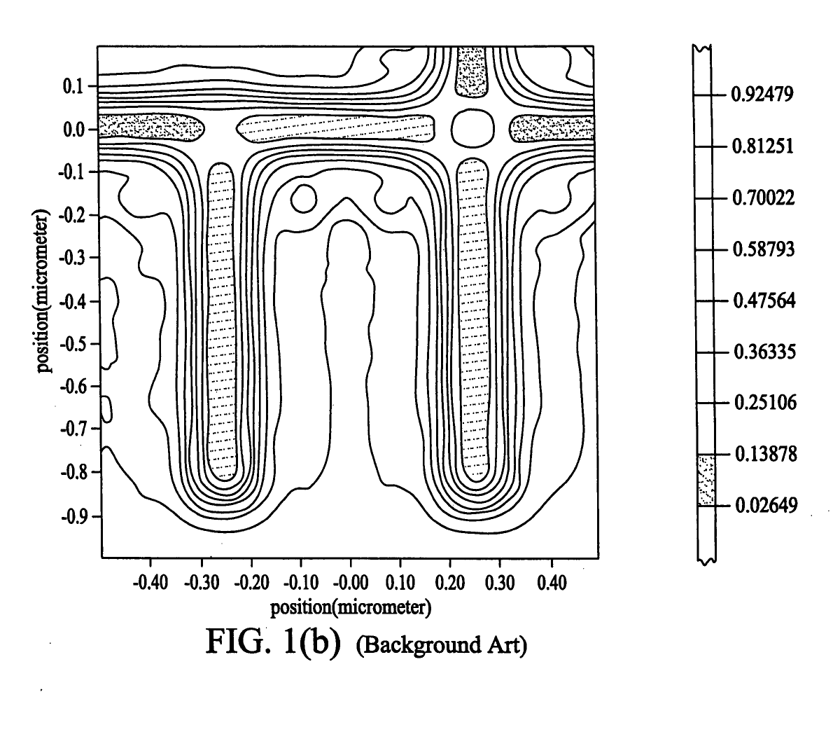

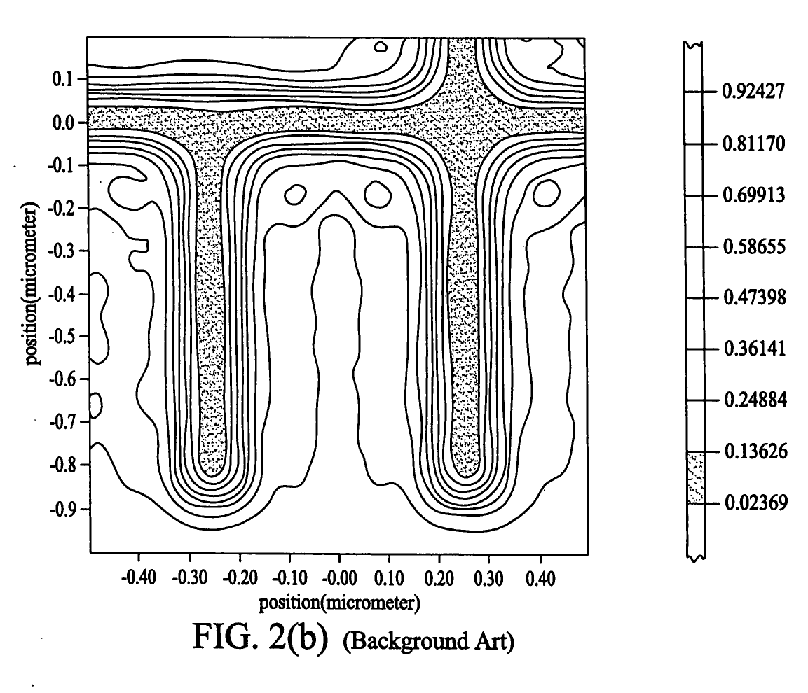

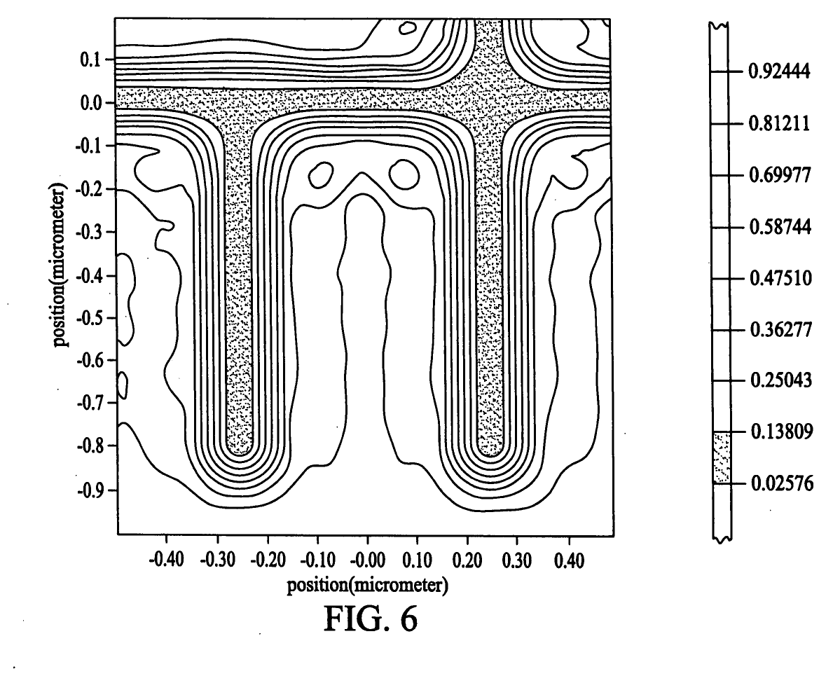

FIG. 6 shows a simulated optical intensity distribution on a portion of the chromeless phase shifting mask 50 (i.e., the dashed-line region) using the SOLID-E according to one embodiment of the present invention. In comparison with the chromeless phase shifting mask 40 in FIG. 1(a), the chromeless phase shifting mask 50 in FIG. 3 has one optical correction pattern 72 at the intersection of the phase shifting pattern 70 including polymer material such that the occurrence of the discontinuity at the intersection of the phase shifting pattern 42 can be avoided, as shown in FIG. 6.

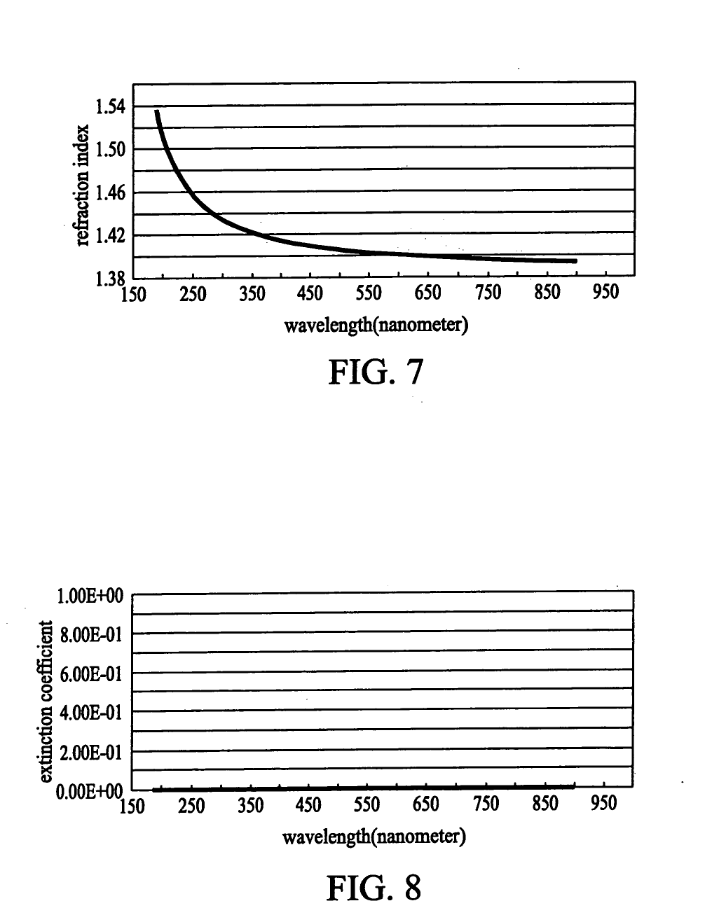

FIG. 7 is a diagram showing the variation of the reflection index of the phase shifting pattern 70 under different wavelengths according to one embodiment the present invention. According to the known phase shifting formula: P=2π(n−1)d/mλ, where, P represents phase shifting angle, n represents the reflection index, d represents the thickness of the phase shifting pattern, m represents an odd number, and λ represents the wavelength of the exposure beam. When the wavelength of the exposure beam is set to be 193 nanometer, the corresponding reflection index is about 1.52, and the thickness of the phase shifting pattern 70 calculated according to the phase shifting formula should be 1828 Å. If the tolerance of the phase shifting angle is set to be 177° to 183°, the thickness of the phase shifting pattern 70 should be 1797 to 1858 nanometers. When the wavelength of the exposure beam is set to be 248 nanometer, the corresponding reflection index is about 1.45, and the thickness of the phase shifting pattern 70 calculated according to the phase shifting formula should be 2713 Å. If the tolerance of the phase shifting angle is set to be 177° to 183°, the thickness of the phase shifting pattern 70 should be 2668 to 2759 nanometers.

FIG. 8 is a diagram showing the variation of the extinction coefficient of the phase shifting pattern 70 under different wavelengths according to one embodiment the present invention. The extinction coefficient of the phase shifting pattern 70 is substantially zero as the wavelength of the exposure beam is between 190 and 900 nanometer. Therefore, the polymer layer 62 is transparent after the irradiation of the electron beam 64, which can be used to prepare the phase shifter for the phase shifting mask.

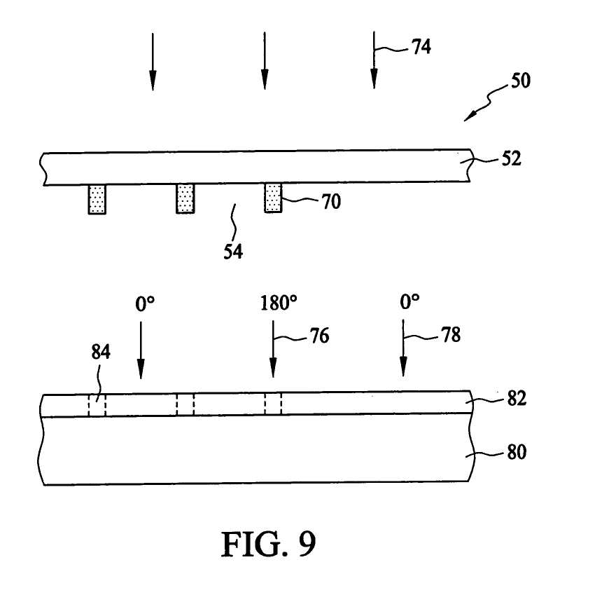

FIG. 9 is a schematic diagram showing the application of the phase shifting mask 50 to pattern the shapes of semiconductor devices on a semiconductor substrate 80 according to one embodiment of the present invention, wherein the phase shifting mask 50 is a cross-sectional view along a cross-sectional line B-B in FIG. 3. The thickness of the phase shifting pattern 70 is designed such that the phase of a transmission beam 76 penetrating through the phase shifting pattern 70 will be lagged by 180 degrees from phase of an exposure beam 74, while the phase of a transmission beam 78 directly penetrating through the substrate 52 maintains the same as that of the exposure beam 74 without lagging, i.e., 0 degrees. As a result, the transmission beam 76 and the transmission beam 78 will form a destructive interference and the optical intensity of the transmission beam 76 counteracts that of the transmission beam 78. Consequently, a lithographic process using the phase shifting mask 50 having the phase shifting pattern 70 can form a plurality of corresponding line-shaped patterns 84 on the photoresist layer 82. The optical correction pattern 72 can be made of material other than that consisting of the polymer layer 62 so long as the difference between the optical correction pattern 72 and the phase shifting pattern 70 can cause phase-lagging between the transmission beams such that the transmission beam 76 can form interference with the transmission beam 78.

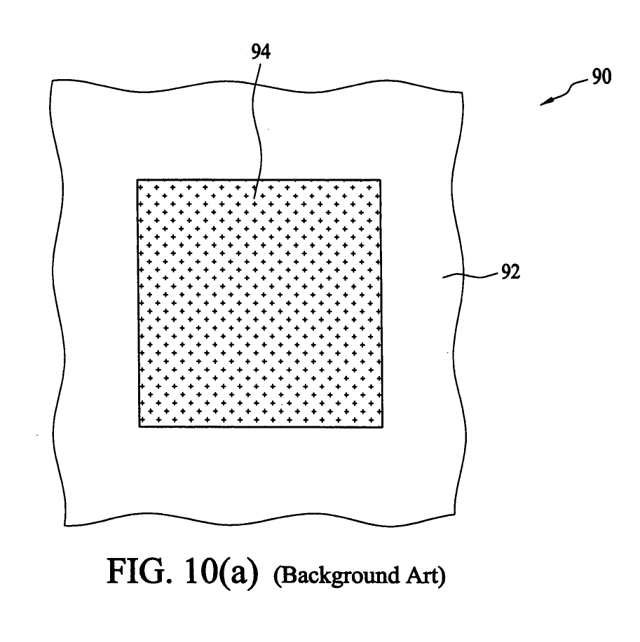

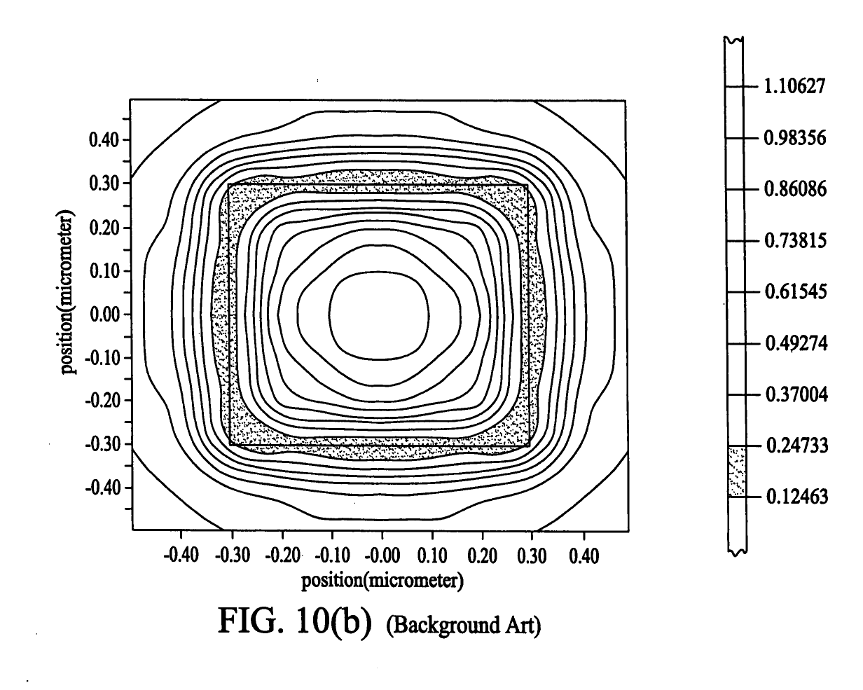

FIG. 10(a) illustrates a chromeless phase shifting mask 90 according to the prior art, and FIG. 10(b) shows simulated optical intensity distribution of the chromeless phase shifting mask 90 using the SOLID-E. The chromeless phase shifting mask 90 comprises a substrate 92 and a rectangular phase shifting pattern 94. The phase shifting pattern 94 is designed such that the phase of an exposure beam penetrating through the phase shifting pattern 94 will be lagged by 180 degrees, while the phase of the exposure beam penetrating through the substrate 52 maintains the same without lagging, i.e., 0 degrees. However, the simulated optical intensity distribution of the chromeless phase shifting mask 90 does not show the desired rectangle, but a rectangular frame, as shown in FIG. 10(b).

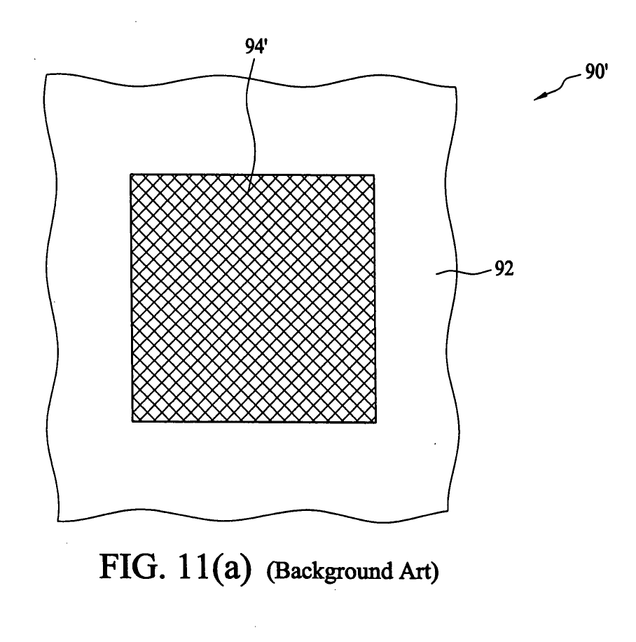

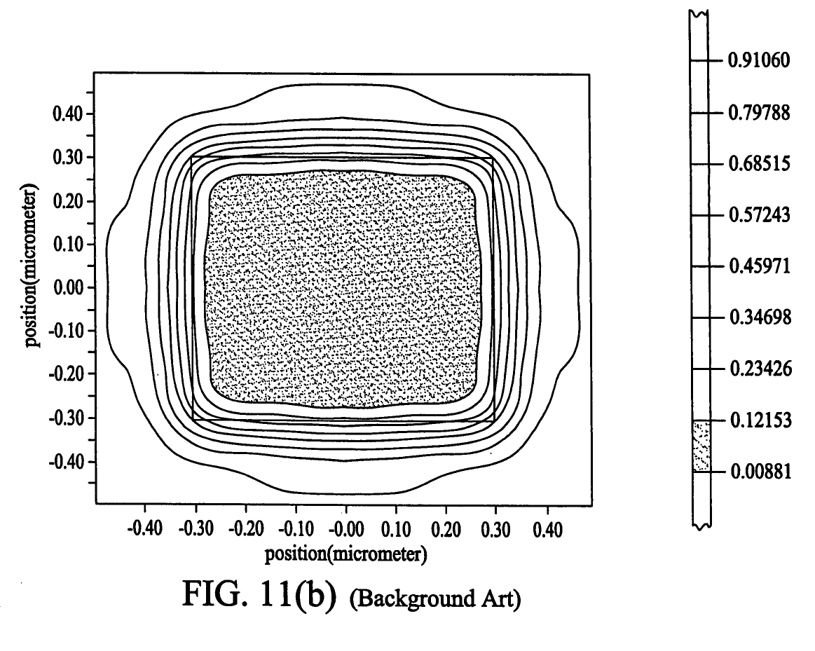

FIG. 11(a) illustrates a phase shifting mask 90′ according to the prior art, and FIG. 11(b) shows simulated optical intensity distribution of the phase shifting mask 90′ using the SOLID-E. In comparison with the chromeless phase shifting mask 90 in FIG. 10(a), the phase shifting mask 90′ further includes an opaque chrome layer 94′ on the rectangular phase shifting pattern 94. The phase shifting mask 90′ can provide a rectangular simulated pattern, i.e., the optical intensity distribution, similar to the designed rectangular phase shifting pattern 94; however, there is a certain difference in size between simulated pattern and the designed rectangular phase shifting pattern 94, as shown in FIG. 11(b).

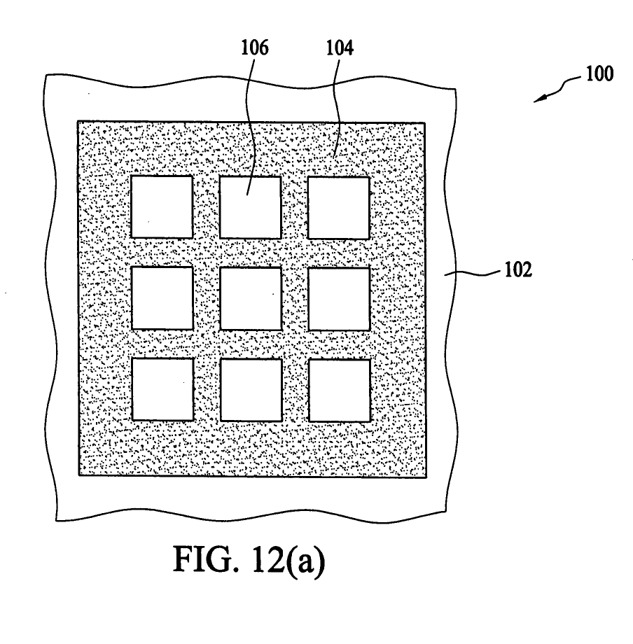

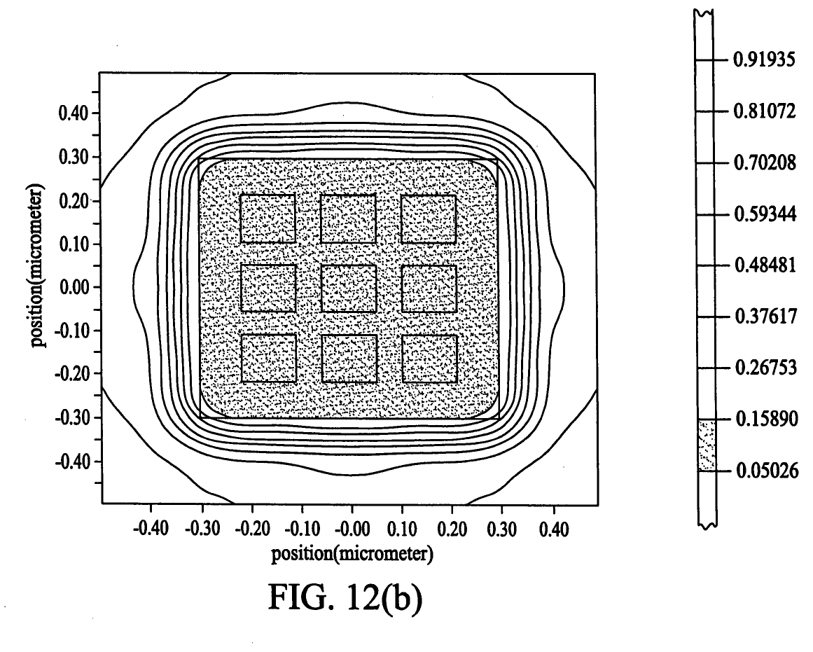

FIG. 12(a) illustrates a chromeless phase shifting mask 100 according to another embodiment of the present invention, and FIG. 12(b) shows a simulated optical intensity distribution of the chromeless phase shifting mask 100 using the SOLID-E. The chromeless phase shifting mask 100 comprises a substrate 102, a phase shifting pattern 104 and a plurality of optical correction patterns 106, wherein the phase shifting pattern 104 surrounds the optical correction pattern 106. The chromeless phase shifting mask 100 provides a simulated pattern, i.e., the optical intensity distribution, similar to the designed phase shifting pattern 104, and the border of the simulated pattern substantially aligns with that of the designed phase shifting pattern 104, i.e., the size of the simulated pattern is substantially the same as that of the designed phase shifting pattern 104, as shown in FIG. 12(b).

In comparison with the prior art using the auxiliary pattern made of chrome to reduce the optical proximity effect, the phase shifting mask in accordance with one embodiment of the present invention comprises an optical correction pattern in the phase shifting pattern to reduce the optical proximity effect. Further, the conventional technique uses the auxiliary pattern made of opaque chrome on the phase shifting pattern to reduce the optical proximity effect. In contrast, rather than using the conventional opaque chrome pattern, one aspect of the present invention solves the pattern distortion issue due to the optical proximity effect by setting transparent optical correction patterns, such as the aperture exposing the substrate, in the phase shifting pattern, with the pattern being made of material including polymer for instance.

Further, the preparation of the conventional chromeless phase shifting mask requires performing the lithographic process twice and etching process, while the preparation of the phase shifting mask according to one embodiment of the present invention does not require performing the lithographic process or etching process such that the throughput of the mask can be increased.

The above-described embodiments of the present invention are intended to be illustrative only. Numerous alternative embodiments may be devised by those skilled in the art without departing from the scope of the following claims.

What is claimed is:

1. A phase shifting mask capable of reducing the proximity effect, comprising:
a substrate;
at least one phase shifting pattern positioned on the substrate; and
at least one optical correction pattern being a transparent region of the substrate, and the phase shifting pattern surrounding the optical correction pattern.

2. The phase shifting mask capable of reducing proximity effect of claim 1, wherein the refraction index of the phase shifting pattern is different from the refraction index of the optical correction pattern.

3. The phase shifting mask capable of reducing the proximity effect of claim 1, wherein the optical correction pattern is an aperture exposing the substrate.

4. The phase shifting mask capable of reducing the proximity effect of claim 1, wherein the phase shifting pattern has a corner and the optical correction pattern is positioned at the corner.

5. The phase shifting mask capable of reducing the proximity effect of claim 1, wherein the phase shifting pattern has an intersection and the optical correction pattern is positioned at the intersection.

6. The phase shifting mask capable of reducing the proximity effect of claim 1, wherein the phase of an exposure beam remains the same after penetrating through the optical correction pattern.

7. The phase shifting mask capable of reducing the proximity effect of claim 1, wherein the phase of an exposure beam penetrating through the phase shifting pattern is different by 180 degrees from the phase of the exposure beam penetrating through the optical correction pattern.

8. A method for preparing a semiconductor device, comprising the steps of:
forming a photoresist layer on a first substrate;
exposing the photoresist layer by using a phase shifting mask including a second substrate and at least one phase shifting pattern positioned on the second substrate, wherein the phase shifting pattern includes a polymer material and surrounds at least one optical correction pattern being a transparent region of the second substrate; and
developing the photoresist layer.

9. The method for preparing a semiconductor device of claim 8, wherein the refraction index of the phase shifting pattern is different from the refraction index of the optical correction pattern.

10. The method for preparing a semiconductor device of claim 8, wherein the optical correction pattern is an aperture exposing the second substrate.

11. The method for preparing a semiconductor device of claim 8, wherein the phase shifting pattern has a corner and the optical correction pattern is positioned at the corner.

12. The method for preparing a semiconductor device of claim 8, wherein the phase shifting pattern has an intersection and the optical correction pattern is positioned at the intersection.

13. The method for preparing a semiconductor device of claim 8, wherein the phase of an exposure beam remains the same after penetrating through the optical correction pattern.

14. The method for preparing a semiconductor device of claim 8, wherein the phase of an exposure beam penetrating through the phase shifting pattern is different by 180 degrees from the phase of the exposure beam penetrating through the optical correction pattern.
